(19) United States
(12) Patent Application Publication
(10) Pub. No.: US 2017/0162668 A1
(43) Pub. Date: Jun. 8, 2017

(54) SEMICONDUCTOR DEVICE AND METHOD OF MANUFACTURING THE SAME

(71) Applicant: SAMSUNG ELECTRONICS CO., LTD., SUWON-SI (KR)

(72) Inventors: SUNG MIN KIM, INCHEON (KR); HEON JONG SHIN, YONGIN-SI (KR)

(21) Appl. No.: 15/348,040

(22) Filed: Nov. 10, 2016

(30) Foreign Application Priority Data
Dec. 7, 2015 (KR) 10-2015-0173138

(51) Int. Cl. H01L 29/66; H01L 29/78; H01L 29/06; H01L 21/762

(52) U.S. Cl. CPC H01L 29/66545; H01L 29/66795; H01L 21/76224; H01L 29/7851; H01L 29/0653

(57) ABSTRACT

A method of manufacturing a semiconductor device includes forming a fin extending in a first direction. A dummy layer is formed including a plurality of semiconductor layers disposed on the fin. Each of the plurality of semiconductor layers have different impurity concentrations from each other. The dummy layer is etched to form a dummy gate electrode.

### CROSS-REFERENCE TO RELATED APPLICATION

This application claims priority under 35 USC §119 to Korean Patent Application No. 10-2015-0173138 filed on Dec. 7, 2015 in the Korean Intellectual Property Office, the disclosure of which is incorporated by reference herein in its entirety.

1. Technical Field

The present inventive concept relates to a semiconductor device, and more particularly to a method of manufacturing the same.

2. Discussion of Related Art

A semiconductor device may include a multi-gate transistor in which a fin-shaped or nanowire-shaped multi-channel active pattern (or silicon body) is formed on a substrate. A gate may be formed on a surface of the multi-channel active pattern.

The multi-gate transistor may include a three-dimensional channel, and the multi-gate transistor may be scaled. Even when the gate length of the multi-gate transistor is not increased, current control capability can be increased. An occurrence of a short channel effect (SCE) of the electric potential of a channel area being influence by a drain voltage may be reduced.

### SUMMARY

One or more exemplary embodiments of the present inventive concept provide a semiconductor device having increased reliability and operating characteristics, and a method of manufacturing the same.

According to an example embodiment of the present inventive concept, a method of manufacturing a semiconductor device includes forming a fin extending in a first direction. A dummy layer is formed including a plurality of semiconductor layers disposed on the fin. Each of the plurality of semiconductor layers has different impurity concentrations from each other. The dummy layer is etched to form a dummy gate electrode.

According to an example embodiment of the present inventive concept, a method of manufacturing a semiconductor device includes forming a fin extending in a first direction. A field insulating film is formed along a relatively longer side of the fin and exposing the upper portion of the fin. A dummy layer is formed on the exposed upper portion fin through a dummy layer deposition process. The dummy layer is etched to form a dummy gate electrode including a concave line formed between the dummy layer and the fin. A spacer is formed on the side wall of the dummy gate electrode to fill the concave line. The dummy gate electrode is with a gate electrode.

### BRIEF DESCRIPTION OF THE DRAWINGS

The above and other features of the present inventive concept will become more apparent by describing in detail exemplary embodiments thereof with reference to the attached drawings, in which:

FIGS. 1 to 10 illustrate a method of manufacturing a semiconductor device according to some exemplary embodiments of the present inventive concept.

FIG. 11 illustrates a step of a method of manufacturing a semiconductor device according to some exemplary embodiments of the present inventive concept.

FIGS. 12 and 13 illustrate steps of a method of manufacturing a semiconductor device according to some exemplary embodiments of the present inventive concept.

FIGS. 14 to 22 illustrate steps of a method of manufacturing a semiconductor device according to some exemplary embodiments of the present inventive concept.

FIG. 23 illustrates a step of a method of manufacturing a semiconductor device according to some exemplary embodiments of the present inventive concept.

FIG. 24 is a block diagram of an electronic system including a semiconductor device according to an exemplary embodiment of the present inventive concept.

FIG. 25 shows an exemplary semiconductor system including the semiconductor device according to an exemplary embodiment of the present inventive concept.

### DETAILED DESCRIPTION OF THE EMBODIMENTS

Aspects of the present inventive concept and methods of accomplishing the same will be described in more detail below with reference to the accompanying drawings, in which some exemplary embodiments are shown. The present inventive concept may, however, be embodied in many different forms and should not be construed as being limited to the embodiments set forth herein. In the specification and drawings, the thickness of layers and/or regions may be exaggerated for clarity.

It will be understood that when an element or layer is referred to as being “on” or “connected to” another element or layer, it may be directly on or connected to the other element or layer or intervening elements or layers may be present. Like reference numbers may refer to like elements throughout the specification and drawings.

It will also be understood that when a layer is referred to as being “on” another layer or substrate, it may be directly on the other layer or substrate, or intervening layers may be present.

It will be understood that, although the terms first, second, etc. may be used herein to describe various elements, these elements should not be limited by these terms.

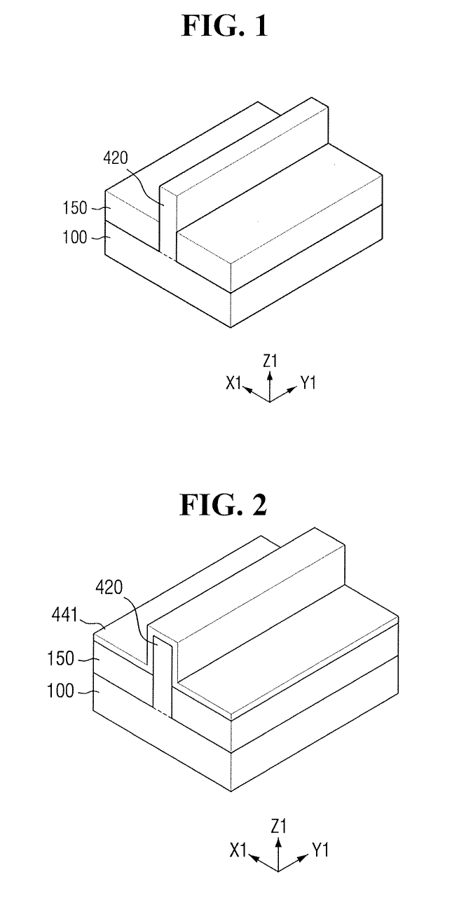

A method of manufacturing a semiconductor device according to some exemplary embodiments of the present inventive concept will be described in more detail below with reference to FIGS. 1 to 10.

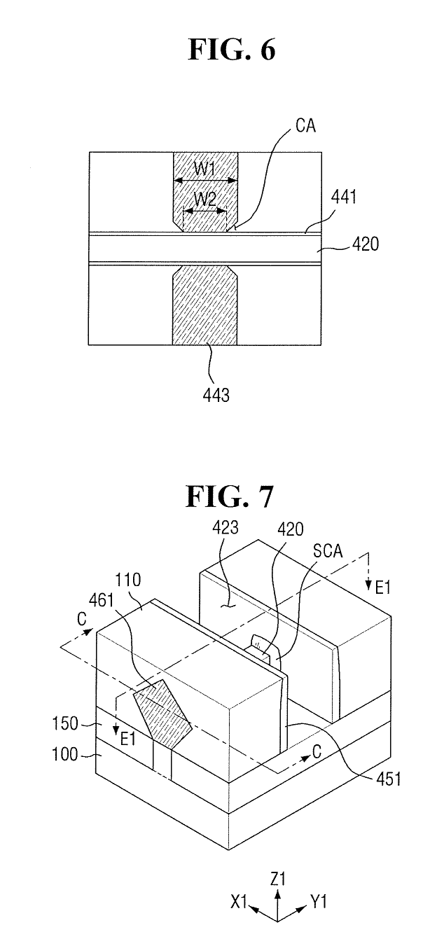

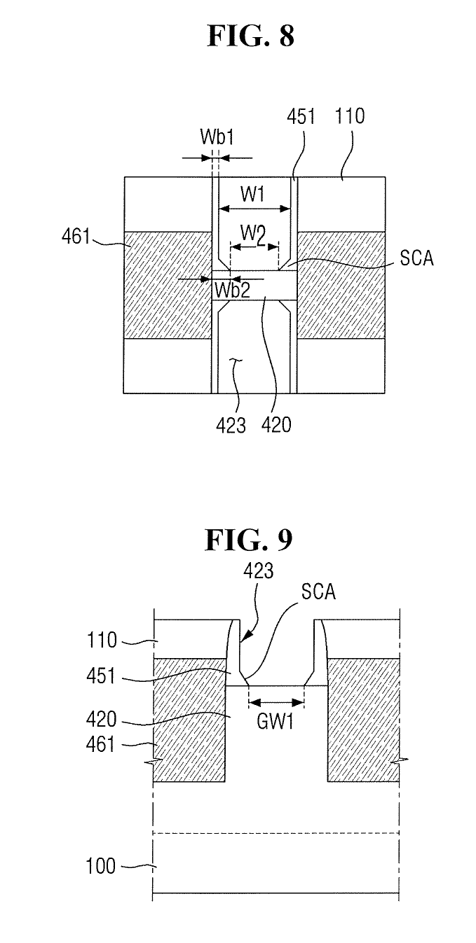

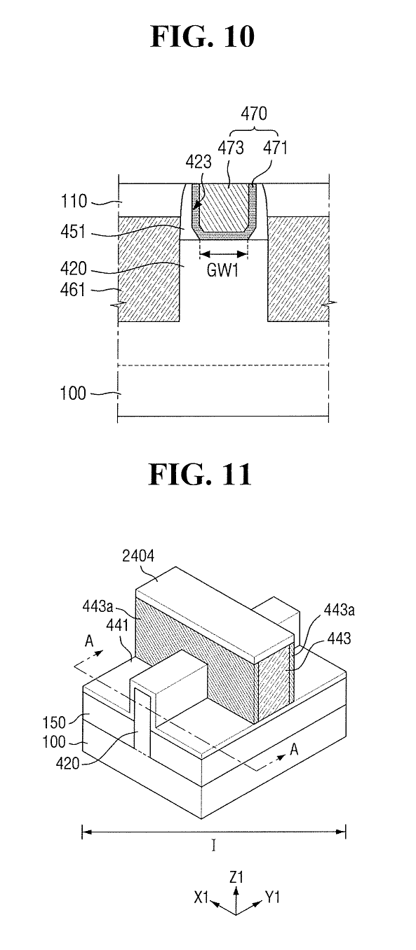

FIGS. 1 to 10 illustrate a method of manufacturing a semiconductor device according to some exemplary embodiments of the present inventive concept. FIGS. 1 to 5 and 7 are perspective views. FIG. 6 is a cross-sectional view taken along the line A-A of FIG. 5. FIG. 8 is a cross-sectional view taken along the line C-C of FIG. 7. FIG. 9 is a cross-sectional view taken along the line E1-E1 of FIG. 7. FIG. 10 is a cross-sectional view taken in the same direction as the cross-sectional view of FIG. 9.

Referring to FIG. 1, a fin 420 may be formed on a substrate 100.

The fin 420 may protrude in a third direction (Z1). The fin 420 may extend along a first direction (Y1), and may have a long side in the first direction (Y1) and a short side in a second direction (X1). However, exemplary embodiments of the present inventive concept are not limited thereto. For example, the fin 420 may have a long side in the second direction (X1) and a short side in the first direction (Y1).

The fin 420 may be a part of the substrate 100, and may include an epitaxial layer grown from the substrate 100. For example, the fin 420 may include silicon (Si) or silicon-germanium (SiGe). The fin 420 may include silicon or germanium, which is an element semiconductor material. The fin 420 may include at least one compound semiconductor, for example, group IV-IV compound semiconductors or group III-V compound semiconductors. Examples of the group IV-IV compound semiconductors may include binary compounds containing at least two of carbon (C), silicon (Si), germanium (Ge), and tin (Sn), ternary compounds, and compounds doped with group IV elements. Examples of the group III-V compound semiconductors may include binary compounds, each of which is formed by bonding of at least one of group III elements, such as aluminum (Al), gallium (Ga), and indium (In), and one of group V elements, such as phosphorous (P), arsenic (As), and antimony (Sb), ternary compound, and quaternary compounds.

The substrate 100 may include at least one semiconductor material selected from Si, Ge, SiGe, GaP, GaAs, SiC, SiGe, InAs, and InP. The substrate 100 may be a silicon on insulator (SOI) substrate.

A field insulating film 150 may cover the lateral sides of the fin 420. The field insulating film 150 may be formed along the long side of the lateral sides of the fin 420. The field insulating film 150 may expose the upper portion of the fin 420. The fin 420 may have a shape protruding in the third direction (Z1) between the field insulating films 150 covering the lateral sides of the fin 420.

Referring to FIG. 2, a dummy gate insulating film 441 may cover the fin 420 and the field insulating film 150. The dummy gate insulating film 441 may be disposed along the upper surface and side walls of the fin 420, and may cover the upper surface of the field insulating film 150. The dummy gate insulating film 441 may be conformally formed on the fin 420 and the field insulating film 150.

The dummy gate insulating film 441 may include one of a silicon oxide (SiO₂) film, a silicon oxynitride (SiON) film, or a combination thereof. The dummy gate insulating film 441 may be formed using heat treatment, chemical treatment, atomic layer deposition (ALD), or chemical vapor deposition (CVD).

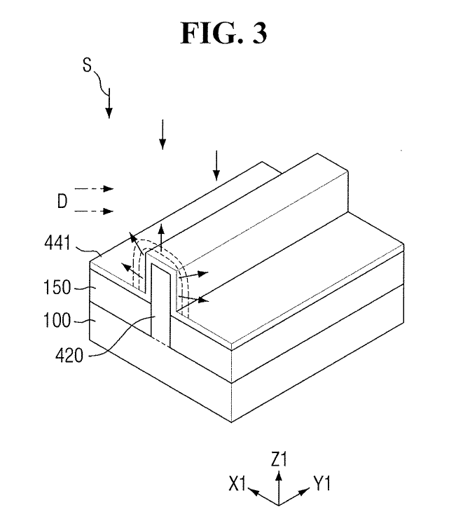

Referring to FIG. 3, a dummy layer deposition process (S) may be performed on the dummy gate insulating film 441. The dummy layer deposition process (S) may form a dummy layer 443, and may include a process of depositing a silicon-based material on the dummy gate insulating film 441. The dummy layer 443, which is formed by the dummy layer deposition process (S), may be formed by the continuous growth of the silicon-based material around the fin 420, but exemplary embodiments of the present inventive concept are not limited thereto.

During the dummy layer deposition process (S), an impurity injection process (D) may be performed. The concentration of impurities included in the dummy layer 443 formed through the dummy layer deposition process (S) can be controlled by adjusting the concentration and amount of impurities injected through the impurity injection process (D). The impurities injected through the impurity injection process (D) may include at least one of germanium (Ge), phosphorus (P), and arsenic (As), or may be impurities that can form the dummy layer 443 into an N-type semiconductor layer. However, exemplary embodiments of the present inventive concept are not limited thereto.

Controlling the concentration of the impurities included in the dummy layer 443 formed through the impurity injection process (D) and the dummy layer deposition process (S) may control the etching rate according to the area of the dummy layer 443.

Thus, any desired impurities can be used regardless of the type of impurities as long as the etching rate according to the area of the dummy layer 443 can be controlled.

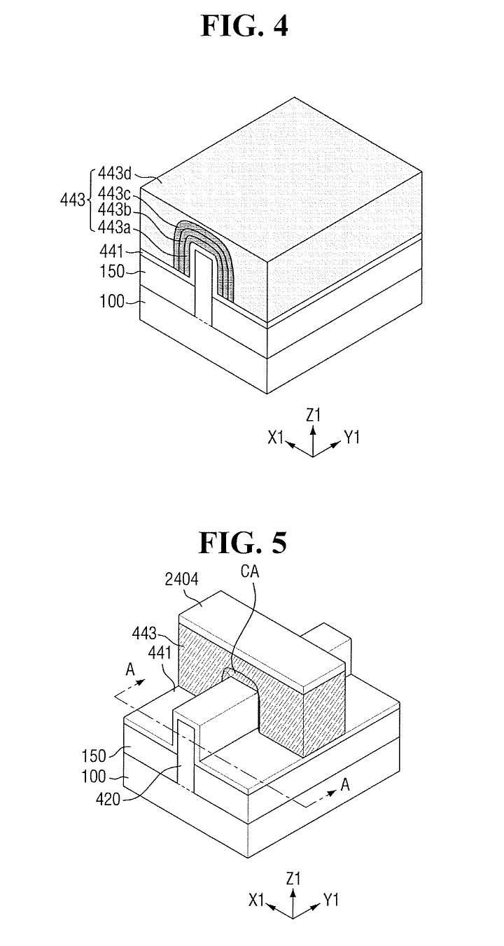

Referring to FIG. 4, the dummy layer 443 including a first semiconductor layer 443a, a second semiconductor layer 443b, a third semiconductor layer 443c, and a fourth semiconductor layer 443d may be formed on the fin 420.

The concentration of impurities included in each of the first semiconductor layer 443a, the second semiconductor layer 443b, the third semiconductor layer 443c, and the fourth semiconductor layer 443d through the impurity injection process (D) can be controlled according to one or more exemplary embodiments of the present inventive concept.

For example, in the case where the impurities used in the impurity injection process (D) is germanium (Ge) and each of the first semiconductor layer 443a, the second semiconductor layer 443b, the third semiconductor layer 443c, and the fourth semiconductor layer 443d includes a silicon-based material, when the concentration and amount of the impurities used in the impurity injection process (D) is increased in the early stage of the dummy layer deposition process (S) and then gradually decreased, the first semiconductor layer 443a may be a silicon-germanium-based material layer having the highest germanium concentration in the dummy layer 443.

The second semiconductor layer 443b may be a silicon-germanium-based material layer having lower germanium concentration than the first semiconductor layer 443a, the third semiconductor layer 443c may be a silicon-germanium-based material layer having lower germanium concentration than the second semiconductor layer 443b, and the fourth semiconductor layer 443d may be a silicon-germanium-based material layer having lower germanium concentration than the third semiconductor layer 443c.

However, exemplary embodiments of the present inventive concept are not limited thereto. For example, in the dummy layer 443, the concentration of the impurities included in the first semiconductor layer 443a may be lowest, and the concentration of the impurities included in the fourth semiconductor layer 443d may be highest.

The dummy layer 443 may include four semiconductor layers, however, exemplary embodiments of the present inventive concept are not limited thereto. The dummy layer 443 may include a plurality of semiconductor layers and each of the semiconductors may have substantially uniform impurity concentrations, however, exemplary embodiments of the present inventive concept are not limited thereto, and each of the plurality of semiconductor layers included in the dummy layer 443 may have impurity concentration changing with a gradient.

Referring to FIG. 5, an etching process may be performed using a mask pattern 2404 to form a dummy gate electrode 443 intersecting with the fin 420 and extending in the second direction (X1).

The dummy gate electrode 443 may include a concave line CA formed along the upper surface and side walls of the fin 420. The concave line CA may be formed in an area corresponding to the area in which the first semiconductor layer 443a of FIG. 4 is formed.

According to an exemplary embodiment of the present inventive concept, the dummy gate electrode 443 may be formed using the dummy layer 443 including the plurality of semiconductor layers. Thus, the dummy gate electrode 443 may have a relatively high impurity concentration in the area closer to the fin 420, and may have a relatively low impurity concentration in the area farther from the fin 420.

Each of the plurality of semiconductor layers included in the dummy layer 443 may have relatively a high etching rate with respect to the same etchant as the concentration of impurity increases. Thus, the plurality of semiconductor layers included in the dummy layer 443 may each have different etching rates from each other. In the first semiconductor layer 443a having the highest impurity concentration, a relatively large area can be etched during a same amount of time, compared to the second to fourth semiconductor layers 443b, 443c, and 443d. Thus, the concave line CA may be formed.

When each of the plurality of semiconductor layers is a silicon-germanium-based material layer, each of the plurality of semiconductor layers may have a relatively high etching rate as the content of germanium increases. Thus, when the dummy gate electrode 443 includes a silicon-germanium-based material, the area of the dummy gate electrode 443, adjacent to the fin 420, may have the highest germanium concentration.

However, exemplary embodiments of the present inventive concept are not limited thereto, and the area having the highest impurity concentration may be variously determined according to the kind of impurities included in particular area. According to some exemplary embodiments of the present inventive concept, the area of the dummy gate electrode 443, adjacent to the fin 420, may maintain a relatively high etching rate, compared to other areas.

The concave line CA may have a line shape, and may be formed along the outside of the fin 420 with a line shape, but exemplary embodiments of the present inventive concept are not limited thereto. The concave line CA may be formed between the fin 420 and the dummy gate electrode 443 intersecting with the fine 420, but exemplary embodiments of the present inventive concept are not limited thereto, and the concave line CA need not be formed by controlling the impurity concentration of each of the plurality of semiconductor layers.

After the formation of the dummy gate electrode 443, a cleaning process using a cleaning solution may be performed. The cleaning solution may be a SCI solution. Through the cleaning process, the concave line CA can be trimmed. That is, through the cleaning process, the formation and depth of the concave line CA can be more precisely controlled. Semiconductor layers having a relatively high impurity concentration can be removed by the cleaning process.

According to an exemplary embodiment of the present inventive concept, since the etching rate of the area of the dummy gate electrode 443, adjacent to the fin 420, with respect to the same etchant is increased, it is possible to reduce or prevent an occurrence of a phenomenon that an etch tail, that is, the dummy layer to be removed, remains between the fin 420 and the dummy gate electrode 443 when forming the dummy gate electrode 443 using the mask pattern 2404. Thus, it is possible to increase the reliability of a semiconductor device and increase the operating characteristics of the semiconductor device.

FIG. 6 is a cross-sectional view taken along the line A-A of FIG. 5.

Referring to FIG. 6 the concave line CA may be formed between the fin 420 and the dummy gate electrode 443.

Since the dummy gate electrode 443 includes the concave line CA, the area in contact with the fin 420 may have a second width W2, and the region spaced from the fin 420 may have a first width W1 larger than the second width W2. The side wall of the concave line CA is shown in the form of a straight line in FIG. 6, but exemplary embodiments of the present inventive concept are not limited thereto. For example, the side wall of the concave line CA may be curved.

Referring to FIGS. 5 and 6, the dummy gate insulating film 441 remains without being patterned or etched, but exemplary embodiments of the present inventive concept are not limited thereto. For example, the dummy gate insulating film 441 may be etched in the same manner as the dummy gate electrode 443. According to some exemplary embodiments of the present inventive concept, the dummy gate insulating film 441 may be etched in the same manner as the dummy gate electrode 443.

Referring to FIGS. 7 to 9, the dummy gate electrode 443 and the dummy gate insulating film 441 may be removed, thus forming a trench 423 intersecting the fin 420 and exposing the fin 420.

A spacer 451 may be formed on the side wall of the dummy gate electrode 443. The spacer 451 may include silicon nitride or silicon oxynitride. When the spacer 451 is formed, a part of the fin 420 not overlapping the dummy gate electrode 443 may be removed to form recesses. A source/drain 461 may be formed at opposite sides of the dummy gate electrode 443. The source/drain 461 may an elevated source/drain area. The source/drain 461 may include Si or SiGe, but exemplary embodiments of the present inventive concept are not limited thereto.

Referring to FIG. 7, the source/drain 461 may have a tetragonal shape, but exemplary embodiments of the present inventive concept are not limited thereto. The source/drain 461 may have a pentagonal shape, a circular shape, or a hexagonal shape, for example.

An interlayer insulating film 110 covering the source/drain 461 may be formed. The interlayer insulating film 110 may include silicon oxide. The upper surface of the dummy gate electrode 443 may be exposed through a planarization process. The dummy gate electrode 443 and the dummy gate insulating film 441 may be removed, thus forming the trench 423.

Referring to FIG. 6, since the concave line CA may be formed between the fin 420 and the dummy gate electrode 443, the spacer 451 formed on the side wall of the dummy gate electrode 443 may include a convex line SCA having a shape corresponding to the shape of the concave line CA.

In the spacer 451, a portion of the spacer 451 covering the upper surface and side wall of the fin 420 may be thicker than other portions of the spacer 451. The spacers 451 facing each other may include the convex lines SCAs facing each other.

Referring to FIGS. 8 and 9 again, the trench 423 may have a first width W1 and a second width W2 smaller than the first width W1. The spacer 451 may have a first width Wb1 and a second width Wb2 larger than the first width Wb1. Thus, the upper surface of the fin 420, exposed through the trench 423, may be exposed with a first gate length GW1.

Referring to FIG. 10, a gate electrode 470 including a gate insulating film 471 and a gate metal layer 473 may be formed in the trench 423.

The gate insulating film 471 may be conformally formed along the upper surface and side wall of the fin 420 and the side wall of the spacer 451. The gate insulating film may include a dielectric material having a higher dielectric constant than silicon oxide. For example, the gate insulating film 471 may include one or more selected from hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. However, exemplary embodiments of the present inventive concept are not limited thereto.

The gate metal layer 473 may include a conductive material. The gate metal layer 473 may include a single layer. However, exemplary embodiments of the present inventive concept are not limited thereto. For example, the gate metal layer 473 may include a work function conductive layer for adjusting a work function and a filling conductive layer for filling the space formed by the work function conductive layer.

The gate metal layer 473 may contain at least one of TiN, WN, TaN, Ru, TiC, TaC, Ti, Ag, Al, TiAl, TiAlN, TiAlC, TaCN, TaSiN, Mn, Zr, W, and Al. The gate metal layer 473 may include Si or SiGe in addition to one or more metals.

The gate electrode 470 may be in contact with the upper surface of the fin 420 exposed through the trench 423 with the first gate length GW1.

A method of manufacturing a semiconductor device according to some exemplary embodiments of the present inventive concept will be described in more detail below with reference to FIG. 11.

FIG. 11 illustrates a step of a method of manufacturing a semiconductor device according to some exemplary embodiments of the present inventive concept. The method of manufacturing a semiconductor device according to this exemplary embodiment may be added to the method of manufacturing a semiconductor device that has been described in more detail above with reference to FIGS. 1 to 10. That is, the intermediate of FIG. 11 may be a step between the steps described with reference to FIGS. 4 and 5. Thus, the same reference numeral as described above may refer to the same elements, and duplicative descriptions may be omitted.

Referring to FIG. 11, the dummy gate electrode 443 may be formed by etching the dummy layer, and then an oxide film 443a may be formed on the exposed side wall of the dummy gate electrode 443.

The oxide film 443a may be formed by oxidizing the side wall of the dummy gate electrode 443. Subsequently, a wet etching process may be performed.

As described in more detail above with reference to FIG. 4, the impurity concentration of the area of the dummy gate electrode 443, adjacent to the fin 420, may be relatively high. Thus, the depth of the formed oxide film 443a may depend on the concentration of impurities included in the dummy gate electrode 443, and the area of the oxide film 443a, adjacent to the fin 420, may be oxidized more thickly.

In the wet etching process, since the difference in etching rate occurs depending on the degree of oxidization of the oxide film 443a, the depth or shape of the formed concave line CA can be controlled more precisely.

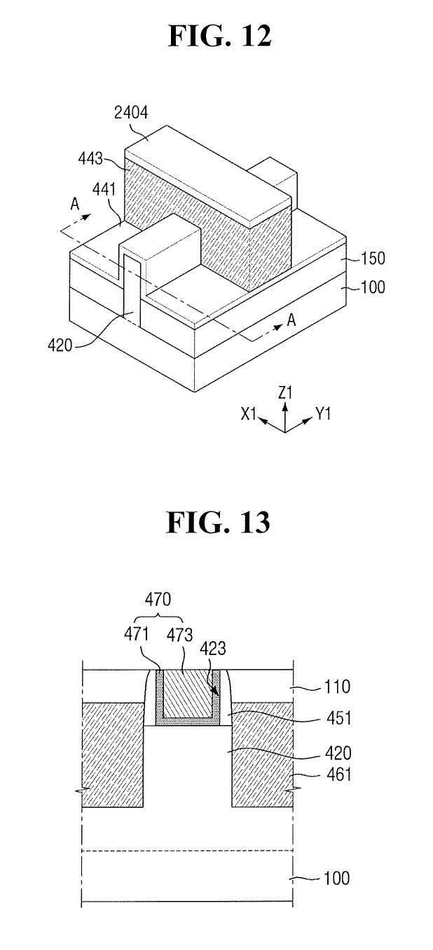

A method of manufacturing a semiconductor device according to some exemplary embodiments of the present inventive concept will be described in more detail below with reference to FIGS. 12 and 13.

FIGS. 12 and 13 illustrate steps of a method of manufacturing a semiconductor device according to some exemplary embodiments of the present inventive concept.

In a method of manufacturing a semiconductor device according an exemplary embodiment of the present inventive concept, the step described with reference to FIG. 12 may correspond to the step FIG. 5, and the step described with reference to FIG. 13 may correspond to the step described with reference to FIG. 10. The same reference numerals illustrated in FIGS. 12 and 13 may be substantially the same as the same reference numerals described above, and thus repeated descriptions may be be omitted.

Referring to FIG. 12, the dummy gate electrode 443 may be formed on the fin 420. The dummy gate electrode 443 might not include the concave line CA. That is, in the dummy gate electrode 443, the side wall of the dummy gate electrode 443 may be flattened by controlling each of the plurality of semiconductor layers included in the dummy layer 443.

Thus, the side wall of the spacer 451 corresponding to the side wall of the dummy gate electrode 443 may have a flat shape, and thus a gate electrode 470 having a shape illustrated in FIG. 13 may be formed.

According to an exemplary embodiment of the present inventive concept, since the dummy layers 443 (see, e.g., FIG. 4) may have different impurity doping concentrations from each other, the dummy gate electrode 443 having a flat side wall (see, e.g., FIG. 12), may be formed, or the dummy gate electrode 443 having the concave line CA (see, e.g., FIG. 5), may be formed.

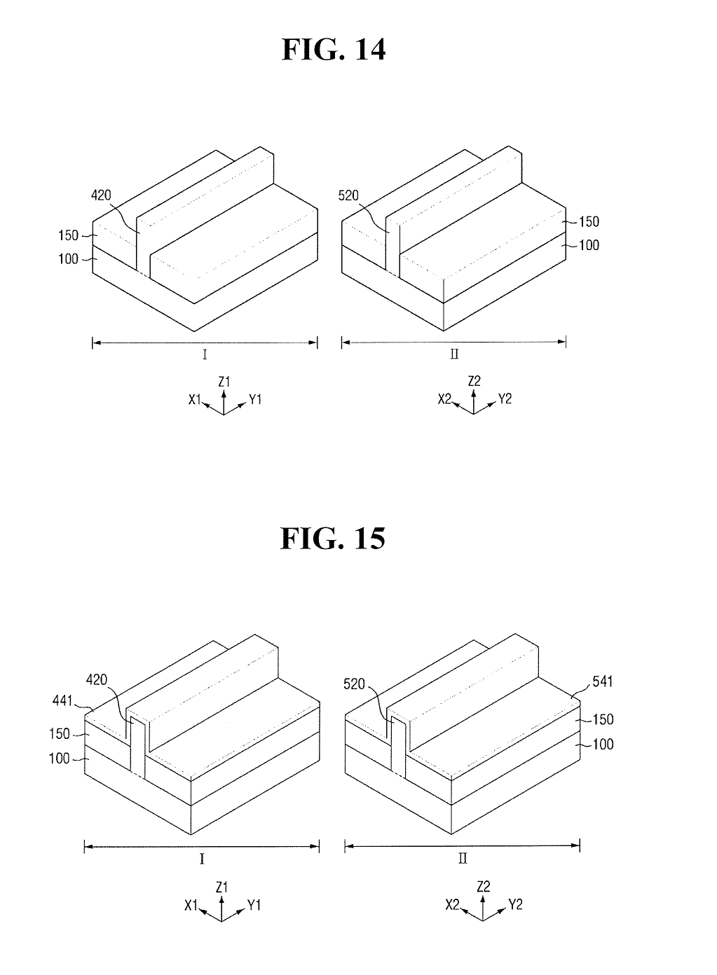

A method of manufacturing a semiconductor device according to some exemplary embodiments of the present inventive concept will be described in more detail below with reference to FIGS. 14 to 22.

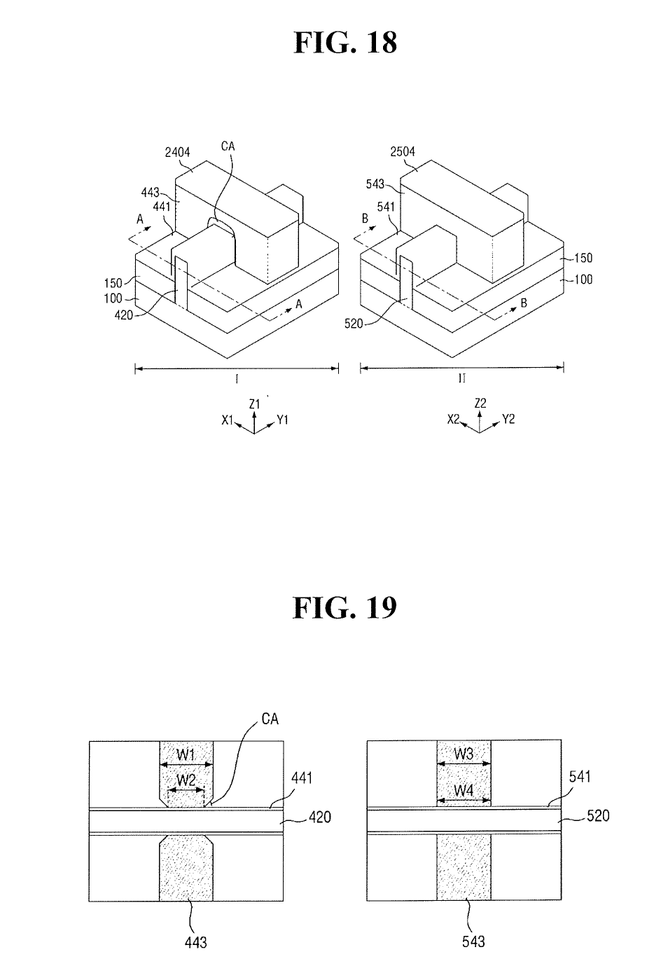

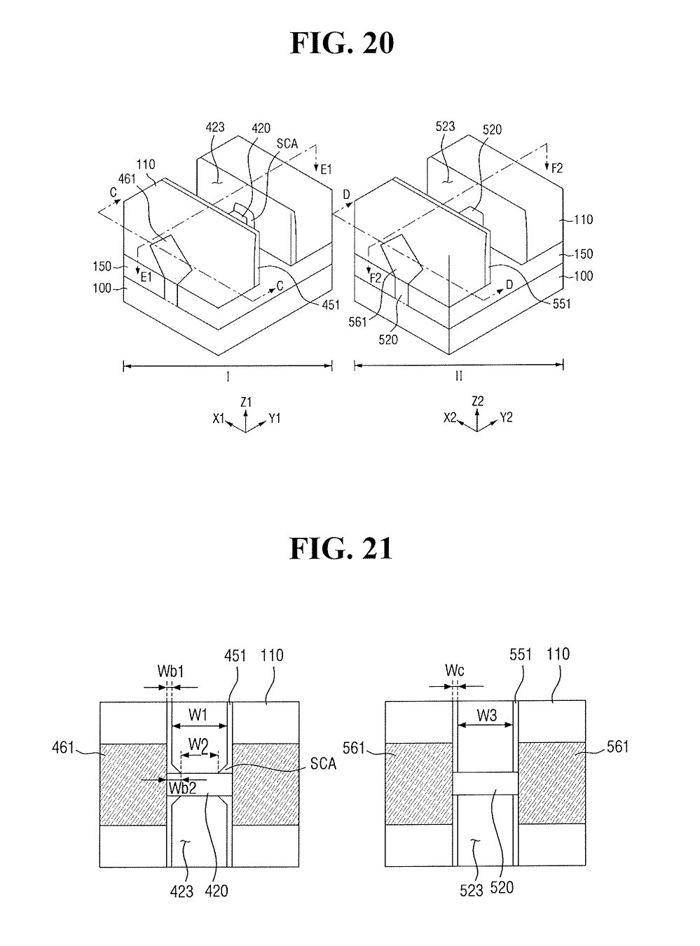

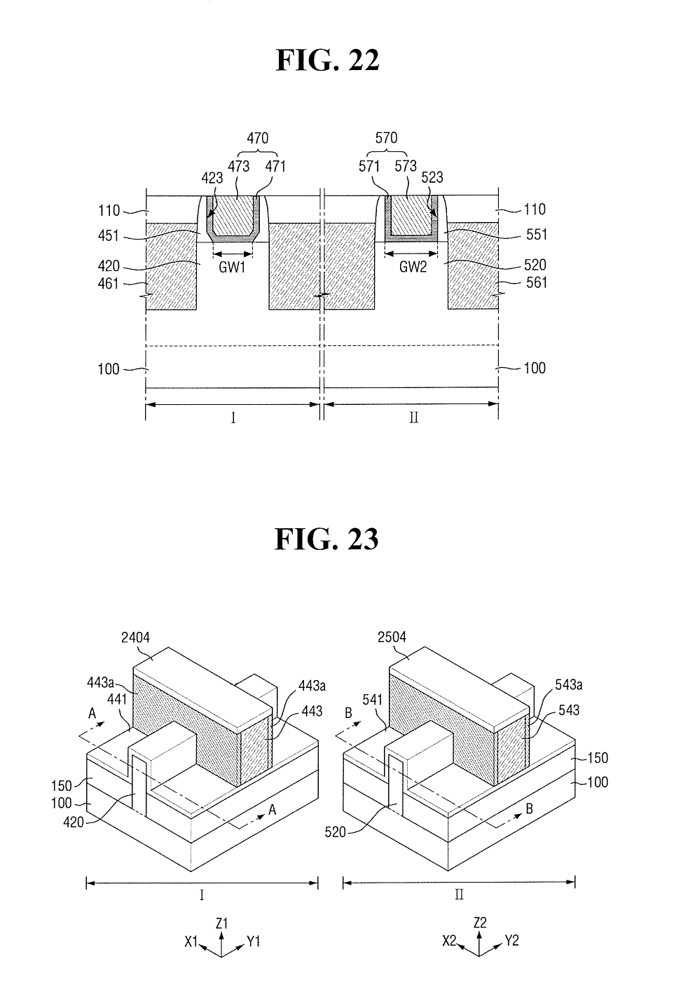

FIGS. 14 to 22 illustrate steps of a method of manufacturing a semiconductor device according to some exemplary embodiments of the present inventive concept. FIGS. 14 to 18 and 20 are perspective views. FIG. 19 shows cross-sectional views taken along the lines A-A and B-B of FIG. 18. FIG. 21 shows cross-sectional views taken along the lines C-C and D-D of FIG. 20. FIG. 22 shows cross-sectional views taken along the lines E1-E1 and F2-F2 of FIG. 20.

According to an exemplary embodiment of the present inventive concept, a method of manufacturing a semiconductor device described with reference to FIGS. 14 to 22, which may include a first area and a second area, may be substantially the same as the method of manufacturing a semiconductor device that has been described with reference to FIGS. 1 to 10. Thus, the same reference numeral as described above may refer to the same elements, and duplicative descriptions may be omitted.

Referring to FIG. 14, the first fin 420 and a second fin 520 may be respectively formed on substrates 100. The substrates 100 may be respectively defined by a first area I and a second area II. The first area I and the second area II may be attached to each other or spaced from each other. For example, the first area I may be an NFET area in which an N-type transistor is formed, and the second area II may be a PFET area in which a P-type transistor is formed. However, exemplary embodiments of the present inventive concept are not limited thereto.

A field insulating film 150 may be formed on each of the substrate 100. The field insulating film 150 may cover the side wall of each of the first and second fins 420 and 520. The field insulating film 150 may include at least one of a silicon oxide film, a silicon nitride film, and a silicon oxynitride film.

Referring to FIG. 15, the first dummy gate insulating film 441 may be formed in the first area I, and a second dummy gate insulating film 541 may be formed in the second area II.

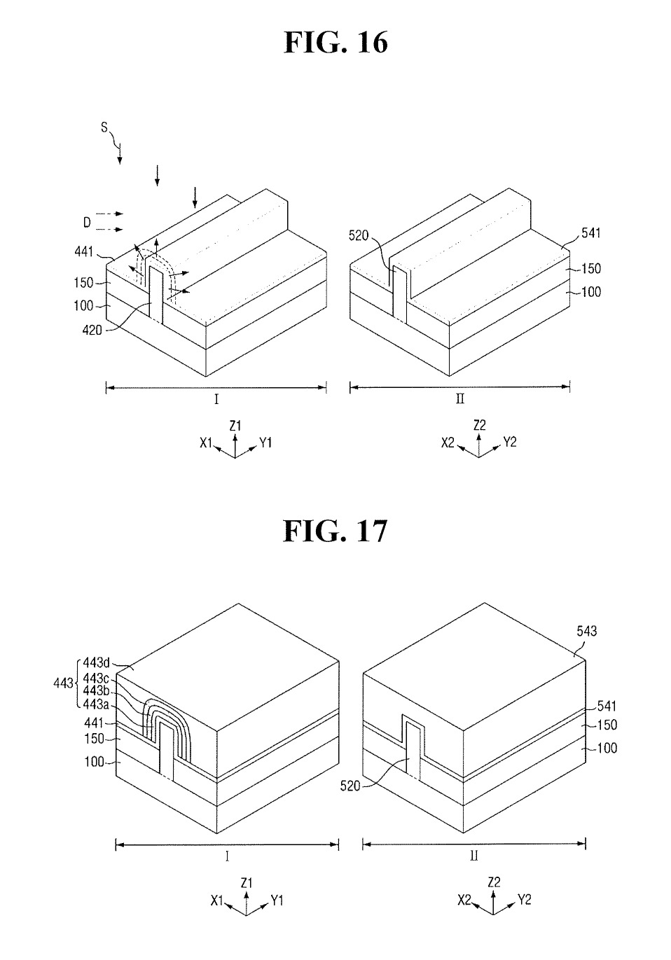

Referring to FIG. 16, a first dummy layer deposition process S using impurity doping gas D may be performed in the first area I. According to an exemplary embodiment of the present inventive concept, a mask layer might not be disposed in the second area II, but exemplary embodiments of the present inventive concept are not limited thereto. A mask layer may be disposed in the second area II and thus the deposition process might be performed only in the first area I.

Referring to FIG. 17, the first dummy layer 443 including first to fourth semiconductor layers 443a, 443b, 443c, and 443d may be formed in the first area I through the first dummy layer deposition process S. A second dummy layer 543 may be formed in the second area II. The second dummy layer 543 may be formed through a process that is substantially the same as or different from the first dummy layer deposition process S.

Referring to FIGS. 18 and 19, the first dummy gate electrode 443 and a second dummy gate electrode 543 may be respectively formed by etching the first area I and the second area II.

After a first mask 2404 is disposed on the first dummy layer 443 and a second mask 2504 is disposed on the second dummy layer 543, the first dummy gate electrode 443 and the second dummy gate electrode 543 may be formed through an etching process.

In the first area I, a concave line CA may be formed between the first dummy gate electrode 443 and the first fin 420. In the second area II, a concave line CA may be formed between the second dummy gate electrode 543 and the second fin 520.

Thus, the area of the first dummy gate electrode 443, adjacent to the first fin 420, may have a second width W2 and a first width W1 larger than the second width W2. The area of the second dummy gate electrode 543, adjacent to the second fin 520, may have a third width W3 and a fourth width W4 substantially equal to the third width W3.

A dummy gate electrode including the concave line CA may be freely formed in the first area I, and another dummy gate electrode not including the concave line CA may be freely formed in the second area II.

Referring to FIGS. 20 to 22, the first trench 423 may be formed in the first area I, and a second trench 523 may be formed in the second area II.

The first spacer 451 formed in the first area I may include a convex line SCA corresponding to the concave line CA. Thus, the area of the first spacer 451, adjacent to the first fin 420, may have a first thickness Wb1, and the area of the first spacer 451, spaced from the fin 420, may have a second thickness Wb2 larger than the first thickness Wb1. A second spacer 551 formed in the second area II may have a substantially uniform thickness Wc.

A source/drain 561 may be formed at opposite sides of the second dummy gate electrode 543. The source/drain 561 may an elevated source/drain area. The source/drain 561 may include Si or SiGe, but exemplary embodiments of the present inventive concept are not limited thereto.

Referring to FIG. 22, the first gate electrode 470 including a first gate insulating film 471 and a first gate metal layer 473 may be formed in the first trench 423 of the first area I, and a second gate electrode 570 including a second gate insulating film 571 and a second gate metal layer 573 may be formed in the second trench 523 of the second area II.

The first gate electrode 470 may be in contact with the first fin 420 and may have a first gate length GW1. The second gate electrode 570 may be in contact with the second fin 520 and may have a second gate length GW2. Since the first spacer 451 includes the convex line SCA, first gate length GW1 may be shorter than the second gate length GW2.

A method of manufacturing a semiconductor device according to some exemplary embodiments of the present inventive concept will be described in more detail below with reference to FIG. 23.

FIG. 23 illustrates a step of a method of manufacturing a semiconductor device according to some exemplary embodiments of the present inventive concept. The method of manufacturing a semiconductor device described with reference to FIG. 23 may be added to the method of manufacturing a semiconductor device that has been described in more detail with reference to FIGS. 14 to 22. That is, the step(s) described with reference to FIG. 23 may be performed between the steps described with reference to FIGS. 17 and 18. Thus, the same reference numeral as described above may refer to the same elements, and duplicative descriptions may be omitted.

Referring to FIG. 23, the first dummy gate electrode 443 may be formed by etching the first dummy layer, and then a first oxide film 443a may be formed on the exposed side wall of the first dummy gate electrode 443. The second dummy gate electrode 543 may be formed by etching the second dummy layer, and then a second oxide film 543a may be formed on the exposed side wall of the second dummy gate electrode 543. But, the second oxide film 543a need not be formed.

The first oxide film 443a may be formed by oxidizing the side wall of the first dummy gate electrode 443. Subsequently, a wet etching process may be performed.

The impurity concentration of the area of the first dummy gate electrode 443, adjacent to the first fin 420, may be relatively high. Thus, the depth of the formed first oxide film 443a may depend on the concentration of impurities included in the first dummy gate electrode 443, and the area of the first oxide film 443a, adjacent to the first fin 420, may be oxidized more thickly.

In the wet etching process, since the difference in etching rate occurs depending on the degree of oxidization of the first oxide film 443a, the depth or shape of the formed concave line CA can be controlled more precisely.

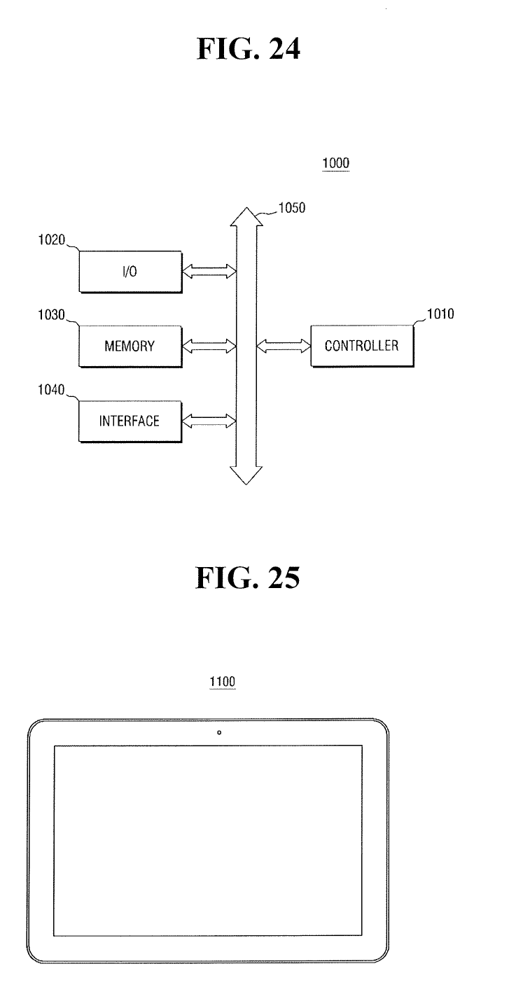

FIG. 24 is a block diagram of an electronic system including a semiconductor device according to an exemplary embodiment of the present inventive concept.

Referring to FIG. 24, the electronic system 1000 according to an embodiment of the present inventive concept may include a controller 1010, an input/output (I/O) device 1020, a memory device 1030, an interface 1040, and a bus 1050. The controller 1010, the input/output (I/O) device 1020, the memory device 1030, and/or the interface 1040 may be connected with each other through the bus 1050. The bus 1050 corresponds to a path through which data are transmitted.

The controller 1010 may include at least one of a microprocessor, a digital signal processor, a microcontroller, and logic devices capable of performing similar functions thereto. The input/output (I/O) device 1020 may include a keypad, a keyboard, and a display device. The memory device 1030 may store data and/or instructions. The interface 1040 may perform a function of transmitting data to a communication network or receiving data from the communication network. The interface 1040 may be a wired or wireless interface. For example, the interface 1040 may include an antenna, a wired transceiver, and a wireless transceiver.

The electronic system 1000 may include high-speed DRAM and/or SRAM as an operation memory for increasing the operation of the controller 1010. The electronic system may include the semiconductor device according to one or more exemplary embodiments of the present inventive concept.

The electronic system 1000 can be applied to all electronic products capable of transmitting and/or receiving information under wireless environments, such as personal digital assistants (PDA), portable computers, web tablets, wireless phones, mobile phones, digital music players, and memory cards.

FIG. 25 shows an exemplary semiconductor system including the semiconductor device according to an exemplary embodiment of the present inventive concept.

FIG. 25 shows a tablet PC 1100. The tablet PC 1100 may include the semiconductor device according to one or more exemplary embodiments of the present inventive concept. The semiconductor device according to one or more exemplary embodiments of the present inventive concept may be included in a notebook computer, or a smart phone.

Further, it is obvious to those skilled in the art that the semiconductor device according to some exemplary embodiments of the present inventive concept can also be applied to other integrated circuit devices that are not exemplified. In some exemplary embodiments of the present inventive concept, examples of the semiconductor system may include UMPCs (Ultra Mobile PCs), work stations, net-books, PDA (Personal Digital Assistants), portable computers, wireless phones, mobile phones, e-boos, PMPs (portable multimedia players), portable game machines, navigators, black boxes, digital cameras, 3-dimensional televisions, digital audio recorders, digital audio players, digital picture recorders, digital picture players, digital video recorders, and digital video players.

While the present inventive concept has been particularly shown and described with reference to exemplary embodiments thereof, it will be understood by those of ordinary skill in the art that various changes in form and detail may be made therein without departing from the spirit and scope of the present inventive concept.

What is claimed is:

1. A method of manufacturing a semiconductor device, comprising:
forming a fin extending in a first direction;
forming a dummy layer including a plurality of semiconductor layers disposed on the fin, wherein each of the plurality of semiconductor layers has different impurity concentrations from each other; and
etching the dummy layer to form a dummy gate electrode.

2. The method of claim 1,
wherein each of the plurality of semiconductor layers has different etching rates from each other with respect to the same etchant according to the different impurity concentrations for each of the semiconductor layers.

3. The method of claim 1,
wherein the impurity concentration of each of the plurality of semiconductor layers increases as it is closer to the fin.

4. The method of claim 3,
wherein an impurity doped in each of the plurality of semiconductor layers is at least one of germanium (Ge), phosphorus (P), and arsenic (As).

5. The method of claim 3,
herein the etching rate of each of the plurality of semiconductor layers increases as the purity concentration increases.

6. The method of claim 3,
wherein the impurity concentration is changed with a gradient in each of the plurality of semiconductor layers.

7. The method of claim 1, wherein the forming the dummy gate electrode comprises forming a concave line along an upper surface and a side wall of the fin between the dummy gate electrode and the fin.

8. The method of claim 7, wherein the forming the dummy gate electrode comprises cleaning the dummy gate electrode with a cleaning solution to trim the concave line.

9. The method of claim 7, wherein the forming the dummy gate electrode comprises oxidizing the surface of the dummy gate electrode, and etching an oxidized surface of the dummy gate electrode.

10. The method of claim 1, wherein the forming the dummy layer comprises forming the dummy layer through a dummy layer deposition process, wherein the dummy layer deposition process includes an impurity injection process of injecting impurities, and wherein the concentration of the impurities injected in the impurity injection process is lowered over time.

11. The method of claim 1, further comprising:
forming a spacer on a side wall of the dummy gate electrode; and
replacing the dummy gate electrode with a gate electrode.

12. A method of manufacturing a semiconductor device, comprising:
forming a fin extending in a first direction;
forming a field insulating film formed along a relatively longer side of the fin and exposing the upper portion of the fin;
forming a dummy layer on the exposed upper portion fin through a dummy layer deposition process;
etching the dummy layer to form a dummy gate electrode including a concave line formed between the dummy layer and the fin;
forming a spacer on the side wall of the dummy gate electrode to fill the concave line; and
replacing the dummy gate electrode with a gate electrode.

13. The method of claim 12, wherein the dummy layer deposition process includes an impurity injection process of injecting impurities, and wherein the concentration of the impurities injected in the impurity injection process is lowered over time.

14. The method of claim 13, wherein the impurities injected in the impurity injection process include at least one of germanium (Ge), phosphorus (P), and arsenic (As).

15. The method of claim 13, wherein the dummy layer includes a plurality of semiconductor layers having different impurity concentrations form each other, and wherein the etching rates of the plurality of semiconductors with respect to the same etchant increase as the impurity concentrations increase.

16. A method of manufacturing a semiconductor device, comprising:
forming a fin on a substrate;
forming a field insulating film formed on first and second side surfaces of the fin;
forming a dummy gate insulating film conformally covering upper surfaces of the field insulating film, the first and second side surfaces of the fin, and an upper surface of the fin;
performing a dummy layer deposition process and an impurity injection process to form a dummy layer including a plurality of semiconductor layers disposed on the fin, wherein each of the plurality of semiconductor layers has different impurity concentrations from each other; and
etching the dummy layer to form a dummy gate electrode.

17. The method of claim 16, wherein the impurity concentration of each of the plurality of semiconductor layers increases as it is closer to the fin.

18. The method of claim 16, wherein an impurity doped in each of the plurality of semiconductor layers is at least one of germanium (Ge), phosphorus (P), and arsenic (As).

19. The method of claim 17, wherein the etching rate of each of the plurality of semiconductor layers increases as the purity concentration increases.

20. The method of claim 17, wherein the impurity concentration is changed with a gradient in each of the plurality of semiconductor layers.
